(19) United States
(12) Patent Application Publication
(10) Pub. No.: US 2014/0084447 A1
(43) Pub. Date: Mar. 27, 2014

(54) POWER MODULE PACKAGE

(71) Applicant: SAMSUNG ELECTRO-MECHANICS CO., LTD., Suwon (KR)

(72) Inventors: Jung Eun Kang, Suwon (KR); Jin Su Kim, Suwon (KR); Kwang Soo Kim, Suwon (KR)

(21) Appl. No.: 13/940,070

(22) Filed: Jul. 11, 2013

(30) Foreign Application Priority Data
Sep. 26, 2012 (KR) 10-2012-0106989

(51) Int. Cl. H01L 23/34

(52) U.S. Cl. CPC H01L 23/34
USPC 257/713

(57) ABSTRACT

Disclosed herein is a power module package including: a body member having a polyhedral shape and made of a metal material; a semiconductor device mounted on the body member; and a block member formed at an edge region of the body member and made of a metal material.

### CROSS REFERENCE TO RELATED APPLICATION

This application claims the benefit of Korean Patent Application No. 10-2012-0106989, filed on Sep. 26, 2012, entitled “Power Module Package”, which is hereby incorporated by reference in its entirety into this application.

### BACKGROUND OF THE INVENTION

1. Technical Field

The present invention relates to a power module package.

2. Description of the Related Art

In accordance with an increase in energy usage over the world, the use of a power conversion device such as an inverter in fields such as home appliances, industrial products, or the like has increased in order to effectively use energy and protect the environment.

An intelligent power module (IPM) that has been prominent in accordance with the increase in the use of the inverter, and also disclosed in Patent Document 1 is a core component performing direct current (DC) rectification and alternate current (AC) conversion in the inverter and may be used in home appliances such as a refrigerator, a washing machine, an air conditioner, industrial applications such as an industrial motor, or the like, and the next generation applications such as a hybrid electric vehicle (HEV), an electric vehicle (EV), or the like.

Meanwhile, in a general IPM, since a form of a basic structure is difficult to be changed after a package design is complete, capacitance is not easily changed. In addition, in order to remove a heat generated during power conversion, a separate substrate made of a metal material for heat radiation or a heat radiation device are required to be mounted thereon.

[Prior Art Document]

[Patent Document]

(Patent Document 1) U.S. Pat. No. 7,208,819 B

### SUMMARY OF THE INVENTION

The present invention has been made in an effort to provide a power module package capable of easily changing capacitance and having an improved heat radiation property.

According to a preferred embodiment of the present invention, there is provided a power module package, including: a body member having a polyhedral shape and made of a metal material; a semiconductor device mounted on the body member; and a block member formed at an edge region of the body member and made of a metal material.

The body member may be provided with a cooling member mounting hole penetrating through one surface and the other surface among surfaces thereof on which the semiconductor device is not mounted.

The power module package may further include a cooling member formed so as to be inserted into the cooling member mounting hole and made of a metal material.

In the case where the number of semiconductor devices is plural, the body member may be mounted with the plurality of semiconductor devices. The power module package may further include an insulating layer formed on a boundary surface between the body member and the block member.

The power module package may further include a wire connecting the semiconductor device to the block member.

The block member may include coupling parts each formed on both side surfaces thereof in a length direction.

The coupling parts may include a protruded coupling part and a depressed coupling part corresponding to the protruded coupling part.

In the case where the number of body members is plural, the plurality of body members may be coupled to each other through the coupling part of the block member.

The power module package may further include a molding member formed so as to surround the semiconductor device, the block member, and an outer surface of the body member.

According to another preferred embodiment of the present invention, there is provided a power module package including: a body member having a polyhedral shape, provided with a cooling member mounting hole penetrating through one surface and the other surface thereof, and made of a metal material; a semiconductor device mounted on the body member; and a cooling member formed so as to be inserted into the cooling member mounting hole and made of a metal material.

The power module package may further include a block member formed at an edge region of the body member and made of a metal material.

The block member may include coupling parts each formed on both side surfaces thereof in a length direction.

The coupling parts may include a protruded coupling part and a depressed coupling part corresponding to the protruded coupling part.

In the case where the number of body members is plural, the plurality of body members may be coupled to each other through the coupling part of the block member.

The power module package may further include an insulating layer formed on a boundary surface between the body member and the block member.

The power module package may further include a wire connecting the semiconductor device to the block member.

In the case where the number of semiconductor devices is plural, the body member may be mounted with the plurality of semiconductor devices.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view showing a configuration of a power module package in detail according to a preferred embodiment of the present invention;

FIG. 2 is a view showing a configuration in which a molding member is formed in the power module package of FIG. 1;

FIG. 3 is a view showing a block member in detail according to the preferred embodiment of the present invention; and

FIG. 4 is a view showing an example of a plurality of body members coupled to each other according to the preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Power Module Package

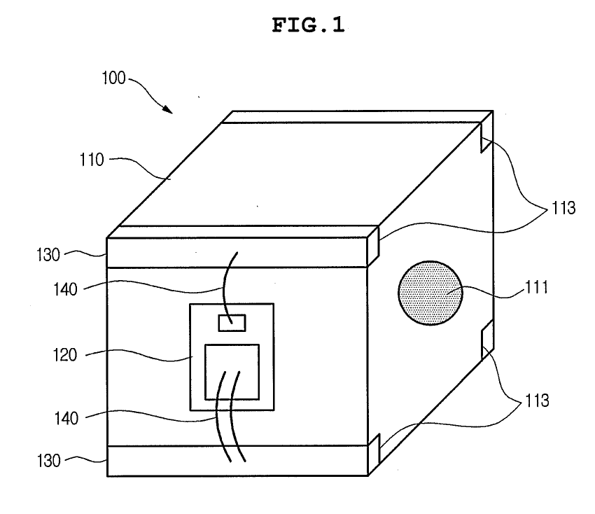

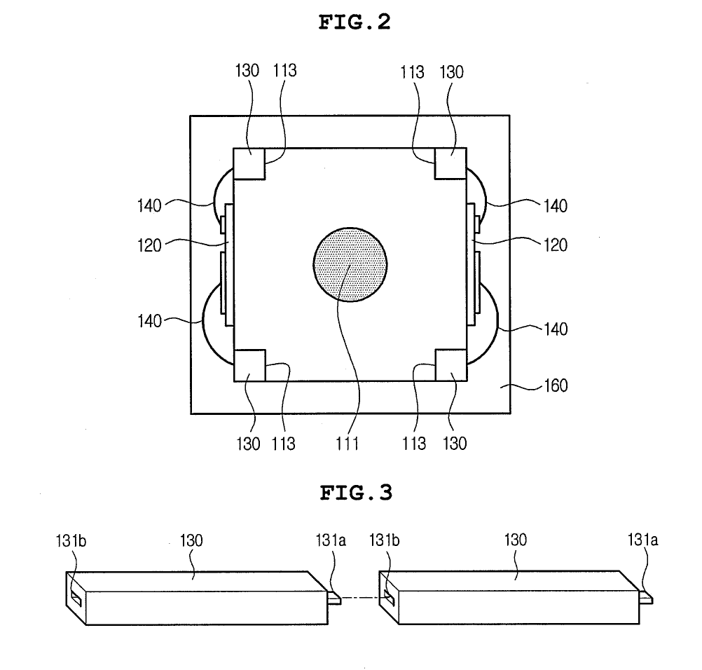

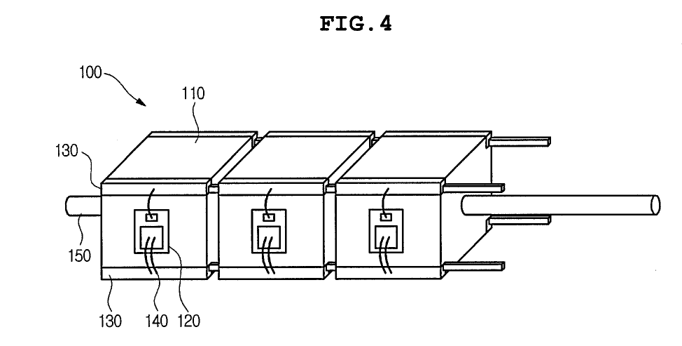

FIG. 1 is a view showing a configuration of a power module package in detail according to a preferred embodiment of the present invention; FIG. 2 is a view showing a configuration in which a molding member is formed in the power module package of FIG. 1; FIG. 3 is a view showing a block member in detail according to the preferred embodiment of the present invention; to and FIG. 4 is a view showing an example of a plurality of body members coupled to each other according to the preferred embodiment of the present invention.

As shown in FIG. 1, the power module package 100 may include a power module package including: a body member 110 having a polyhedral shape and made of a metal material; a semiconductor device 120 mounted on the body member 110; and a block member 130 formed at an edge region of the body member 110 and made of a metal material.

The semiconductor device 120 may be a power device having a large heat generation amount such as insulated gate bipolar transistor (IGBT), diode, or the like, but the present invention is not limited thereto.

The body member 110 may be provided with a cooling member mounting hole 111 penetrating through one surface and the other surface among surfaces thereof on which the semiconductor device 120 is not mounted.

That is, the body member 110 may have a polyhedral shape, and be provided with the cooling member mounting hole 111 penetrating through one surface and the other surface thereof.

In addition, as shown in FIG. 4, the power module package 100 may further include a cooling member 150 formed so as to be inserted into the cooling member mounting hole 111 and made of a metal material.

Here, the cooling member 150 is applicable as far as it is formed of a metal material capable of improving the heat radiation property.

The body member 110 described above may be formed in plural.

As shown in FIG. 4, since the cooling member 150 has a form in which the cooling member 150 is inserted into the cooling member mounting hole 111 formed in each of the plurality of body members 110, it may serve to couple the plurality of body members 110 to each other.

In addition, the cooling member 150 may be made of a metal material having excellent heat radiation property to remove heat generated from the semiconductor device 120, thereby improving the heat radiation property of the power module package 100.

Since a power module package generally configures a heatsink, or the like, which is a separate configuration for heat radiation, in a lower portion of a substrate on which the semiconductor device is mounted, an area for the heat radiation needs to be secured. However, since the power module package 100 according to the preferred embodiment of the present invention includes the cooling member 150 formed so as to be inserted into the body member 110, securing the area for heat radiation may be omitted to realize an improved power module package in view of miniaturization and degree of integration.

In addition, the cooling member 150 is made of a metal material to perform electrical connection function in the power module package 100.

As shown in FIG. 4, the bar shaped cooling member 150 couples the plurality of body members 110 to one another, thereby making it possible to electrically connect the semiconductor devices 120 mounted on body members 110 neighboring to each other in parallel with each other.

That is, the cooling member 150 and the block member 130 may serve to couple the plurality of body members 110 and perform the electrical connection function.

Here, voltage applied to the cooling member 150 and the block member 130, respectively, may be selectively applied to positive voltage or negative voltage according to the operator's needs.

Due to the above-described structure, it may be expected that the power module package 100 of the present invention may easily change capacitance.

For example, in order to increase the capacitance of the power module package 100 as needed by the operators, the body member 110 is additionally coupled to the other body member 110, and on the contrary, in order to decrease the capacitance, the coupled body member 110 is removed therefrom.

As shown in FIG. 2, the power module package 100 may include the semiconductor device 120 and the block member 130, and further include a molding member 160 formed so as to surround the semiconductor device 120, the block member 130, and an outer surface of the body member 110.

Meanwhile, in FIG. 4, the molding member 160 is omitted for convenience of explanation; however, it is obvious that the plurality of body members 110 are coupled to each other in a state that the molding member 160 surrounding the outer surface of the body member 110 is formed in the power module package 100 as shown in FIG. 2.

As shown in FIG. 2, the semiconductor devices 120 may be formed in plural.

Here, the body member 110 may be provided with the plurality of semiconductor devices 120 mounted thereon.

For example, the body member 110 includes the block member 130 formed at an edge region, have a regular hexahedron form, and is provided with the semiconductor device 120 mounted on each surface except for a surface on which the cooling member mounting hole 111 is formed among surfaces of the regular hexahedron.

Due to the above-described structure, the area in which the semiconductor device 120 may be mounted on the power module package 100 may be secured to improve the efficiency that the semiconductor device 120 is mounted thereon.

In addition, the power module package 100 may further include an insulating layer 113 formed on a boundary surface between the body member 110 and the block member 130.

More specifically, the insulating layer 113 is formed on a surface in which the body member 110 and the block member 130 that are made of a metal material, contact to each other, thereby previously preventing a short-circuit phenomenon that may be generated therebetween.

In addition, the power module package 100 may further include a wire 140 connecting the semiconductor device 120 to the block member 130.

As shown in FIG. 1, the block member 130 may be formed at an edge region of the body member 110, and more particularly, formed at the edge region corresponding to both side surfaces of the body member 110 on which the semiconductor device 120 is mounted.

That is, the block member 130 is formed on both side surfaces of the body member 110 so as to be electrically connected to the semiconductor device 120 based on the surface of the body member 110 on which the semiconductor device 120 is mounted.

The block member 130 may be electrically connected to the semiconductor device 120 through the wire 140.

In addition, as shown in FIG. 3, the block member 130 may further include coupling parts (131a, 131b) each formed on both side surfaces thereof in a length direction.

Here, the coupling parts 131a and 131b may include a protruded coupling part 131a and a depressed coupling part 131b corresponding to the protruded coupling part 131a; however, the present invention is not limited thereto. Therefore, the coupling parts capable of being coupled to each other and having various shapes can be applied to the present invention according to the operator's needs.

The protruded coupling part 131a and the depressed coupling part 131b described above may have a size and a form corresponding to each other, respectively, so as to be coupled to each other.

Here, the meaning of the word ‘corresponding’ is that the protruded coupling part 131a and the depressed coupling part 131b to be coupled to the corresponding coupling part have the same size and the same form, corresponding to the change of the protruded coupling part 131a or the depressed coupling part 131b.

However, the same does not mean thickness of dimensions that are accurately the same in mathematics, but means the thickness of dimensions that are substantially the same in consideration of errors in design, in manufacture, in measurement, or the like.

As shown in FIG. 4, the body member 110 may be formed in plural.

Here, the plurality of body members 110 may be physically coupled to each other and may be electrically connected to each other through the coupling parts 131a and 131b of the block member 130.

Meanwhile, in the block member 130, the configuration of the coupling parts 131a and 131b may be omitted and the plurality of block members 130 may be coupled to each other using an adhesive. Here, the adhesive may be made of a conductive material for electrical connection between the block members 130.

The general power module package is difficult to change the capacitance according to the operator's needs after being manufactured; however, the power module package 100 according to the preferred embodiment of the present invention may be provided with the plurality of semiconductor devices 120 mounted on the body member 110, and the plurality of body members 110 may be physically coupled to each other and electrically connected to each other; such that the capacitance may be easily changed by increasing or decreasing the number of semiconductor devices 120 or the number of body members 110 according to the operator's needs.

In the power module package according to the preferred embodiments of the present invention, the plurality of semiconductor devices may be mounted on the body member, thereby making it possible to maximize the efficiency that the semiconductor device is mounted thereon.

In addition, according to the preferred embodiments of the present invention, the plurality of semiconductor devices may be mounted on the body member or the plurality of body members may be coupled to each other, thereby making it possible to easily change the capacitance of the power module package.

Further, in the power module package according to the preferred embodiments of the present invention, since the body member and the cooling member may be implemented integrally with each other, the separate heat radiation module may be omitted and thereby, the power module package may be miniaturized.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A power module package comprising:
a body member having a polyhedral shape and made of a metal material;
a semiconductor device mounted on the body member; and
a block member formed at an edge region of the body member and made of a metal material.

2. The power module package as set forth in claim 1, wherein the body member is provided with a cooling member mounting hole penetrating through one surface and the other surface among surfaces thereof on which the semiconductor device is not mounted.

3. The power module package as set forth in claim 2, further comprising a cooling member formed so as to be inserted into the cooling member mounting hole and made of a metal material.

4. The power module package as set forth in claim 2, wherein in the case where the number of semiconductor devices is plural, the body member is mounted with the plurality of semiconductor devices.

5. The power module package as set forth in claim 1, further comprising an insulating layer formed on a boundary surface between the body member and the block member.

6. The power module package as set forth in claim 1, further comprising a wire connecting the semiconductor device to the block member.

7. The power module package as set forth in claim 1, wherein the block member includes coupling parts each formed on both side surfaces thereof in a length direction.

8. The power module package as set forth in claim 7, wherein the coupling parts include a protruded coupling part and a depressed coupling part corresponding to the protruded coupling part.

9. The power module package as set forth in claim 7, wherein in the case where the number of body members is plural, the plurality of body members are coupled to each other through the coupling part of the block member.

10. The power module package as set forth in claim 1, further comprising a molding member formed so as to surround the semiconductor device, the block member, and an outer surface of the body member.

11. A power module package comprising:
a body member having a polyhedral shape, provided with a cooling member mounting hole penetrating through one surface and the other surface thereof, and made of a metal material;
a semiconductor device mounted on the body member; and
a cooling member formed so as to be inserted into the cooling member mounting hole and made of a metal material.

12. The power module package as set forth in claim 11, further comprising a block member formed at an edge region of the body member and made of a metal material.

13. The power module package as set forth in claim 11, wherein the block member includes coupling parts each formed on both side surfaces thereof in a length direction.

14. The power module package as set forth in claim 13, wherein the coupling parts include a protruded coupling part and a depressed coupling part corresponding to the protruded coupling part.

15. The power module package as set forth in claim 13, wherein in the case where the number of body members is plural, the plurality of body members are coupled to each other through the coupling part of the block member.

16. The power module package as set forth in claim 12, further comprising an insulating layer formed on a boundary surface between the body member and the block member.

17. The power module package as set forth in claim 12, further comprising a wire connecting the semiconductor device to the block member.

18. The power module package as set forth in claim 11, wherein in the case where the number of semiconductor devices is plural, the body member is mounted with the plurality of semiconductor devices.
